(19) United States
(12) Patent Application Publication
(10) Pub. No.: US 2025/0091805 A1
(43) Pub. Date: Mar. 20, 2025

(54) APPARATUS OF ABSORBING VIBRATION FOR TRANSFERRING VEHICLE AND TRANSFERRING VEHICLE SYSTEM COMPRISING THE SAME

(71) Applicant: SEMES CO., LTD., Chungcheongnam-do (KR)

(72) Inventor: Jae Hyun LEE, Gyeonggi-do (KR)

(21) Appl. No.: 18/885,343

(22) Filed: Sep. 13, 2024

(30) Foreign Application Priority Data
Sep. 14, 2023 (KR) 10-2023-0122128

(51) Int. Cl. B65G 1/04; F16F 7/116

(52) U.S. Cl. CPC B65G 1/0464; F16F 7/116

(57) ABSTRACT

An apparatus of absorbing a vibration for a transferring vehicle that absorbs a vibration of the transferring vehicle, the transferring vehicle including a driving unit and two pairs of wheels, includes: a support shaft supporting the transferring vehicle above a base plate provided between the transferring vehicle and a hoist; and a first vibration absorbing unit provided on the base plate and reducing twisting of the base plate, wherein the first vibration absorbing unit includes: a reinforcing plate provided above the base plate; and a plurality of first springs provided to be spaced apart from each other at an edge of the reinforcing plate and elastically support the reinforcing plate between the reinforcing plate and the base plate.

### CROSS-REFERENCE TO RELATED APPLICATION

This application claims priority from Korean Patent Application No. 10-2023-0122128 filed on Sep. 14, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an apparatus of absorbing a vibration for a transferring vehicle and a transferring vehicle system comprising the same.

### 2. Description of the Related Art

Semiconductor (display) fabricating processes are processes for fabricating semiconductor elements on a substrate (e.g., a wafer), and include, for example, exposing, depositing, etching, ion implanting, cleaning, packaging, and the like. The semiconductor fabricating processes are performed in clean rooms of one or more layers of a semiconductor fabricating plant for fabricating semiconductor elements, and fabricating facilities for performing the semiconductor fabricating processes are disposed in the respective layers.

In order to maximize efficiency of the semiconductor fabricating processes, not only methods for improving the respective semiconductor fabricating processes but also techniques for quickly and efficiently transferring an article (e.g., a substrate) between the respective fabricating facilities have been introduced. Typically, an overhead hoist transport (OHT) system has been applied as a transferring vehicle system that transfers an article along a path installed on the ceiling of the semiconductor fabricating plant. The OHT system includes a rail constituting a traveling path and a transferring vehicle transferring an article while traveling along the rail. In addition, when storage of the article is required during transfer of the article between semiconductor fabricating facilities, a storage system for storing the article may be provided.

The transferring vehicle loads and unloads the article in order to perform an assigned operation, and repeats traveling and stopping operations. The transferring vehicle may load and unload the article by raising and lowering a hoist griping the article.

Meanwhile, when the transferring vehicle performs quick sliding driving or performs curved line traveling or the like in order to increase an article loading and unloading speed of the transferring vehicle, a vibration of the transferring vehicle may be transmitted to the hoist to cause damage to the article.

### SUMMARY

Aspects of the present disclosure provide an apparatus of absorbing a vibration for a transferring vehicle capable of minimizing a vibration transmitted from the transferring vehicle to a hoist, and a transferring vehicle system comprising the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, an apparatus of absorbing a vibration for a transferring vehicle that absorbs a vibration of the transferring vehicle, the transferring vehicle including a driving unit and two pairs of wheels, includes: a support shaft supporting the transferring vehicle above a base plate provided between the transferring vehicle and a hoist; and a first vibration absorbing unit provided on the base plate and reducing twisting of the base plate, wherein the first vibration absorbing unit includes: a reinforcing plate provided above the base plate; and a plurality of first springs provided to be spaced apart from each other at an edge of the reinforcing plate and elastically support the reinforcing plate between the reinforcing plate and the base plate.

According to another aspect of the present disclosure, a transferring vehicle system includes: a transferring vehicle including a driving unit and two pairs of wheels; and the apparatus of absorbing a vibration for a transferring vehicle as described above.

According to still another aspect of the present disclosure, a transferring vehicle system includes: a transferring vehicle including a driving unit and two pairs of wheels; and an apparatus of absorbing a vibration including a base plate which is provided between the transferring vehicle and a hoist and in which a first through hole having a step and a second through hole positioned to be spaced apart from the first through hole are formed, a support shaft supporting the transferring vehicle above the base plate, a first vibration absorbing unit provided on the base plate and reducing twisting of the base plate, and a second vibration absorbing unit provided on the base plate and absorbing a vertical vibration of the base plate, wherein the first vibration absorbing unit includes: a reinforcing plate in which a first through-hole vertically facing the first through hole, a second through-hole spaced apart from the first through-hole, and a third-through hole spaced apart from the second through-hole and vertically facing the second through hole are formed and which is provided above the base plate; a damper supporting the reinforcing plate so that the base plate and the reinforcing plate are not in contact with each other and are spaced apart from each other; four first springs provided to be spaced apart from each other at an edge of the reinforcing plate, elastically support the reinforcing plate between the reinforcing plate and the base plate, and in contact with and supported by the step of the first through hole; a first vertical shaft surrounded by the first springs, penetrating through each of the first through hole and the first through-hole, and provided with an expansion plate having a greater diameter than the first through hole; a first cover covering an upper end of the first vertical shaft and coupled to the first vertical shaft; and first blocks provided between the first cover and the reinforcing plate and between the expansion plate and the base plate, made of a metal material, and having a ring shape, the second vibration absorbing unit includes: a vertical vibration absorbing spring elastically supporting a lower portion of the support shaft; a second vertical shaft surrounded by the vertical vibration absorbing spring and penetrating through each of the second through hole and the third through-hole; and a guider which is in contact with the vertical vibration absorbing spring and into which the second vertical shaft is inserted, the damper includes a second cover coupled to an upper surface of the reinforcing plate at a central portion of the reinforcing plate to cover the second through-hole and a second spring in contact with the second cover to elastically support the reinforcing plate, the guider includes a support pillar coupled into the second through hole, supporting the vertical vibration absorbing spring, and having an lower end that are expanded, and a second block provided between the base plate and the support pillar, and the second vertical shaft has an upper end that is expanded, is elastically supported on an upper end of the vertical vibration absorbing spring, and is provided to be vertically slidable in the support pillar.

Detailed contents of other embodiments are described in a detailed description and are illustrated in the drawings.

With an apparatus of absorbing a vibration for a transferring vehicle and a transferring vehicle system comprising the same, all sides of a reinforcing plate provided above a base plate are elastically supported by first springs, such that a vibration due to twisting may be absorbed.

In addition, according to the present disclosure, the reinforcing plate elastically supported by the first springs are not in surface contact with the base plate, such that the transferring vehicle and the base plate may be provided in independent forms, and it is thus possible to minimize transmission of a vibration of the transferring vehicle to the base plate.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view illustrating a transferring vehicle system including an apparatus of absorbing a vibration according to a first exemplary embodiment of the present disclosure;

FIG. 2 is a cross-sectional view taken along I-I′ of FIG. 1;

FIG. 3 is a cross-sectional view taken along line II-II′ of FIG. 1;

FIG. 4 is a cross-sectional view taken along line III-III′ of FIG. 3; and

FIG. 5 is a view illustrating a portion of an apparatus of absorbing a vibration according to a second exemplary embodiment of the present disclosure.

### DETAILED DESCRIPTION OF THE EMBODIMENTS

Hereinafter, exemplary embodiments of the present disclosure will be described in detail with reference to the accompanying drawings. Advantages and features of the present disclosure and methods for accomplishing these advantages and features will become apparent from exemplary embodiments to be described later in detail with reference to the accompanying drawings. However, the present disclosure is not limited to exemplary embodiments to be disclosed below, and may be implemented in various different forms, these exemplary embodiments will be provided only in order to make the present disclosure complete and allow one of ordinary skill in the art to which the present disclosure pertains to completely recognize the scope of the present disclosure, and the present disclosure will be defined by the scope of the claims. Throughout the specification, the same components will be denoted by the same reference numerals.

The terms as used herein are for describing exemplary embodiments rather than limiting the present disclosure. In the present specification, a singular form includes a plural form unless stated otherwise in the phrase. The terms “comprise” and/or “comprising” as used herein do not exclude the existence or addition of one or more other components, steps, operations, and/or elements in addition to the mentioned components, steps, operations, and/or elements.

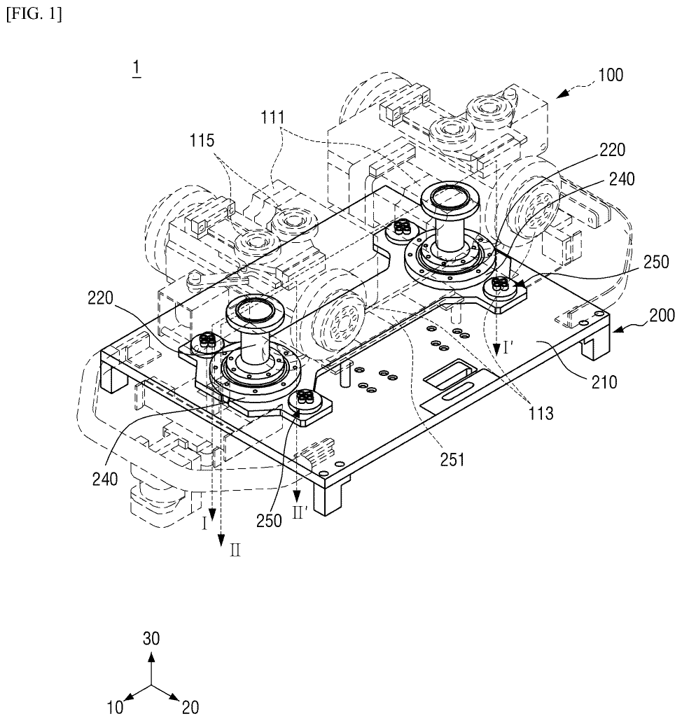

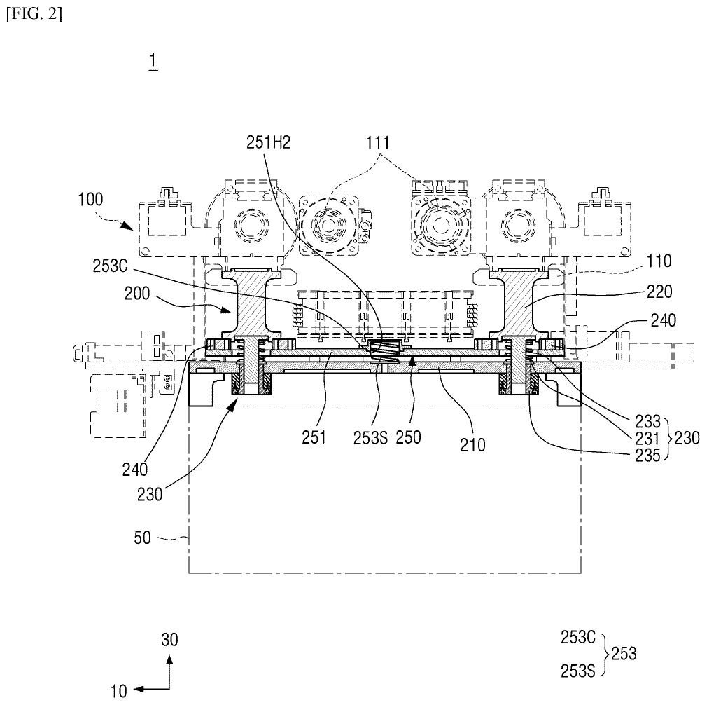

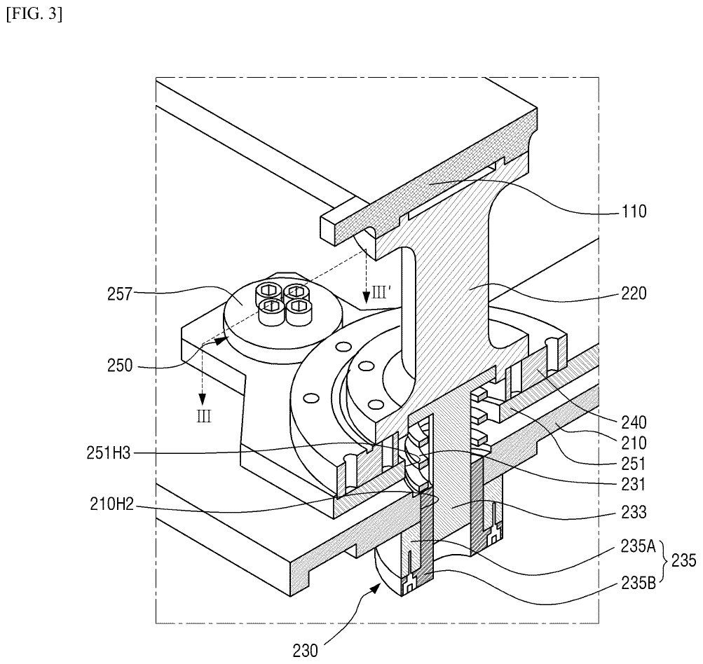

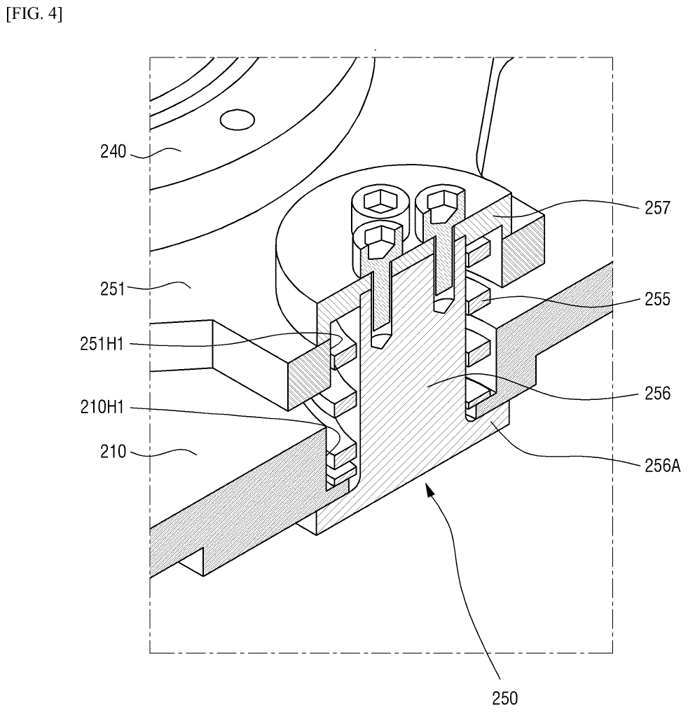

FIG. 1 is a perspective view illustrating a transferring vehicle system including an apparatus of absorbing a vibration according to a first exemplary embodiment of the present disclosure. In addition, FIG. 2 is a cross-sectional view taken along I-I′ of FIG. 1, FIG. 3 is a cross-sectional view taken along line II-II′ of FIG. 1, and FIG. 4 is a cross-sectional view taken along line III-III′ of FIG. 3.

Referring to FIGS. 1 to 4, a transferring vehicle system 1 according to an exemplary embodiment of the present disclosure may include a transferring vehicle 100 and an apparatus 200 of absorbing a vibration for a transferring vehicle.

A fabricating facility (not illustrated) for performing a process may be installed in a semiconductor fabricating line, and a ceiling-type rail (not illustrated) may be provided around the fabricating facility. The transferring vehicle 100 may travel along the ceiling-type rail to transfer an article.

The transferring vehicle 100 includes a driving unit, two pairs of wheels 113, and a steering wheel 115. The driving unit may be provided as a motor 111. Two motors 111 may be provided, and may be individually driven to individually perform forward traveling and backward traveling. As an example, two pairs of wheels 113 may be individually operated by two motors 111.

The steering wheel 115 may be provided to be movable along a horizontal direction perpendicular to a traveling direction. The steering wheel 115 may be in selective contact with a steering track (not illustrated). The steering wheel 115 is movable in a left and right direction, and the traveling direction of the transferring vehicle 100 may be changed through the guidance of the steering track according to the movement of the steering wheel 115.

A base plate 210 to which a hoist 50 is coupled may be provided below the transferring vehicle 100. That is, the transferring vehicle 100 may be installed with the hoist 50 via the base plate 210.

A first through hole 210H1 and a second through hole 210H2 for installing a first vibration absorbing unit 250 and a second vibration absorbing unit 230 may be formed in the base plate 210.

The first through hole 210H1 is a hole in which a first spring 255 and a first vertical shaft 256 are installed (see FIG. 4). The first through hole 210H1 may face a first through-hole 251H1, and the first vertical shaft 256 may penetrate through the first through hole 210H1.

The first spring 255 is in a state in which it is inserted into the first through hole 210H1, and thus, the first spring 255 may not be separated from an installation position. In addition, the first through hole 210H1 may provide a space whose height is greater than a gap between the base plate 210 and a reinforcing plate 251 to allow the first spring 255 to have a vertical length enough to absorb a vibration.

That is, the first through hole 210H1 may be provided so that the first spring 255 has a length enough to absorb the vibration so that it is not difficult to install the first spring 255 due to a small gap between the reinforcing plate 251 and the base plate 210.

In addition, a step may be formed in the first through hole 210H1. The first spring 255 may be in contact with the step of the first through hole 210H1. As another example, several modified examples such as an example in which the step of the first through hole 210H1 is omitted and the first spring 255 is in direct contact with an expansion plate 256A of the first vertical shaft 256 are possible.

The second through hole 210H2 is a hole in which a guider 235 is installed. The second through hole 210H2 may be coupled to a support pillar 235B of the guider 235 (see FIG. 3). The second through hole 210H2 may face a third through-hole 251H3 in a vertical direction, such that a vertical vibration absorbing spring 231 may be supported on the support pillar 235B inserted into the second through hole 210H2.

In addition, a step may be formed in the second through hole 210H2 identically or similarly to the first through hole 210H1, such that the vertical vibration absorbing spring 231 may be in contact with the step of the second through hole 210H2. Here, a level of an upper end of the support pillar 235B is the same as a level of the step of the second through hole 210H2, such that the vertical vibration absorbing spring 231 may be installed so as to be in contact with both the step of the second through hole 210H2 and the support pillar 235B.

The apparatus 200 of absorbing a vibration installed on the base plate 210 may include a support shaft 220, the first vibration absorbing unit 250, and the second vibration absorbing unit 230, and may minimize or prevent transmission of the vibration of the transferring vehicle 100 to the hoist 50.

The support shaft 220 may support the transferring vehicle 100 above the base plate 210. As an example, the support shaft 220 may be coupled to a bracket and/or a frame 110 of the transferring vehicle 100, and an expansion ring 240 may be provided below the support shaft 220. The frame 110 may be a component to which a component of the transferring vehicle 100 such as the motor 111 is coupled, and the expansion ring 240 may expand a support surface of the support shaft 220 between the support shaft 220 and the reinforcing plate 251.

Each of an upper end and a lower end of the support shaft 220 may be fitted into the frame 110 or the expansion ring 240 by having a ring or projection shape protruding therefrom. The support shaft 220 is not only fitted into the frame 110 or the expansion ring 240, but is coupled to the frame 110 or the expansion ring 240 by a bolt, such that fixing force may be improved.

Two support shafts 220 may be provided to be spaced apart from each other in an X-axis direction 10 that is a moving direction of the transferring vehicle 100 (see FIGS. 1 and 2). The support shafts 220 may be provided to be spaced apart from a central portion of the transferring vehicle 100 by an equal distance. The support shaft 220 may be provided adjacent to the motor 111, but is not limited thereto. A vertical vibration of the support shaft 220 may be absorbed by the second vibration absorbing unit 230.

The second vibration absorbing unit 230 is a component absorbing the vertical vibration of the support shaft 220 below the support shaft 220, and may include the vertical vibration absorbing spring 231, a vertical shaft 233, and the guider 235.

The vertical vibration absorbing spring 231 may be provided as, for example, a coil spring, and may elastically support a lower portion of the support shaft 220 and/or an expanded upper end of the second vertical shaft 233. The vertical vibration absorbing spring 231 may penetrate through the third through-hole 251H3 so as to be physically separated from the reinforcing plate 251, and may be disposed at the upper end of the support pillar 235B.

The second vertical shaft 233 may penetrate through the base plate 210 below the support shaft 220. The second vertical shaft 233 may penetrate through each of the second through hole 210H2 and the third through-hole 251H3. The second vertical shaft 233 may be surrounded by the vertical vibration absorbing spring 231, and the expanded upper end of the second vertical shaft 233 may be provided to be in contact with the vertical vibration absorbing spring 231.

The second vertical shaft 233 may be provided to be vertically slidable in a hollow of the support pillar 235B, and may be elastically supported by the vertical vibration absorbing spring 231 together with the support shaft 220. In this case, based on the support pillar 235B, the second vertical shaft 233 moves upward by the vibration absorbing spring 231 or moves downward by its own weight, such that the second vertical shaft 233 and the vibration absorbing spring 231 may serve to damp the vibration of the transferring vehicle 100.

However, the present disclosure is not limited thereto, and as another example, the second vertical shaft 233 is fixed to the hollow of the support pillar 235B, such that the upper end of the second vertical shaft 233 is not expanded, and accordingly, the vibration absorbing spring 231 may be in direct contact with and elastically support the support shaft 220.

The guider 235 may guide the vertical movement of the second vertical shaft 233.

The guider 235 may be in contact with the vertical vibration absorbing spring 231 to prevent the separation of the vertical vibration absorbing spring 231, and may include the support pillar 235B and a second block 235A.

The support pillar 235B may be coupled into the second through hole 210H2. For example, the support pillar 235B may be fixed to the second through hole 210H2 by a method such as press-fitting, adhesion, or welding. The upper end of the support pillar 235B may be in contact with and support the vertical vibration absorbing spring 231. A lower end of the support pillar 235B may be expanded, and the expanded lower end of the support pillar 235B may be connected to the second block 235A by a bolt, a pin, and the like.

The second block 235A may be provided between the base plate 210 and the support pillar 235B, and may expand a space between the base plate 210 and the support pillar 235B.

The second block 235A may have a ring shape, and may be made of a metal material (e.g., aluminum). Alternatively, various modified examples such as a modified example in which the second block 235A is made of a rubber material to absorb a vibration are possible.

Such a second vibration absorbing unit 230 may absorb a vertical vibration generated in the transferring vehicle 100 below the support shaft 220. However, a vibration due to twisting as well as the vertical vibration may be generated in the transferring vehicle 100.

For example, the transferring vehicle 100 may perform curved line traveling as well as straight line traveling. As an example, when the transferring vehicle 100 performs curved line traveling in a right direction, a front right wheel 113 first turns to the right. In this case, imbalance occurs between a region of the base plate 210 where the front right wheel 113 is positioned and the other region, such that the base plate 210 may be twisted.

The twisting of the base plate 210 acts as a cause of a vibration, and thus, there is a need to absorb the vibration caused by the twisting of the base plate 210. The vibration caused by the twisting of the base plate 210 may be absorbed by the first vibration absorbing unit 250. That is, the first vibration absorbing unit 250 is provided on the base plate 210 and reduces the twisting of the base plate 210 to absorb the vibration of the base plate 210.

The first vibration absorbing unit 250 may include the reinforcing plate 251, a damper 253, the first spring 255, the first vertical shaft 256, and a first cover 257 (see FIG. 4).

The reinforcing plate 251 may be provided above the base plate 210 (see FIG. 2). The gap may be formed between the reinforcing plate 251 and the base plate 210 by the damper 253. The reinforcing plate 251 is elastically supported by a plurality of first springs 255 positioned at an edge of the reinforcing plate 251 while being elastically supported by a second spring 253S of the damper 253, such that the reinforcing plate 251 is not in surface contact with the base plate 210, and thus, transmission of a vibration due to surface contact may be minimized or prevented.

Accordingly, the transferring vehicle 100 provided above the reinforcing plate 251 and the base plate 210 may have independent forms in which the transmission of the vibration is minimized.

A penetration structure for installing the first spring 255, the second spring 253S, and the vertical vibration absorbing spring 231 may be formed in the reinforcing plate 251. For example, the first through-hole 251H1, a second through-hole 251H2, and the third through-hole 251H3 may be formed in the reinforcing plate 251.

The first through-hole 251H1 and the second through-hole 251H2 may be provided as holes in which the first spring 255 and the second spring 253S for elastically supporting the reinforcing plate 251 so that the reinforcing plate 251 is not in surface contact with the base plate 210 are installed. That is, the first through-hole 251H1 may be a hole in which the first spring 255 is installed, and may face the first through hole 210H1 in the vertical direction. The second spring 253S may penetrate through the second through-hole 251H2.

The third through-hole 251H3 may be provided as a hole in which the vertical vibration absorbing spring 231 absorbing or damping the vertical vibration is installed, and may face the second through hole 210H2 in the vertical direction.

The damper 253 may support the reinforcing plate 251 so that the base plate 210 and the reinforcing plate 251 are not in contact with each other and are spaced apart from each other. The damper 253 may elastically support a portion between the reinforcing plate 251 and the base plate 210 at a central portion of the reinforcing plate 251.

The damper 253 may include the second spring 253S and a second cover 253C.

The second spring 253S may be provided as a coil spring, and may elastically support the reinforcing plate 251. The second cover 253C may cover the second through-hole 251H2, and may be in contact with the second spring 253S. The second cover 253C may be fixed to the reinforcing plate 251.

However, in the present exemplary embodiment, it has been illustrated that the third through-hole 251H3 is formed in the reinforcing plate 251 and the second cover 253C is provided, but this is to simplify a structure of the reinforcing plate 251. That is, the present disclosure is not limited to an example where the reinforcing plate 251 is provided in a flat plate structure and the third through-hole 251H3 is formed in the reinforcing plate 251 by hole-drilling.

As another example, the reinforcing plate 251 may have a structure in which the third through-hole 251H3 and the second cover 253C are integrated with each other to have a structure in which a concave groove is formed instead of the third through-hole 251H3 and the second cover 253C and the second spring 253S is installed in the concave groove.

The plurality of first springs 255 may be provided to be spaced apart from each other at the edge of the reinforcing plate 251. The first springs 255 may elastically support the reinforcing plate 251 between the reinforcing plate 251 and the base plate 210.

The first springs 255 may be provided to be spaced apart from each other as much as possible from each other at the reinforcing plate 251. Two pairs of first springs 255 may be provided in a front and rear direction or the left and right direction As an example, the first springs 255 may be disposed in pairs in a Y-axis direction 20 based on the support shafts 220 in the Y-axis direction 20 perpendicular to the X-axis direction 10 (see FIG. 1). The first springs 255 may prevent the twisting of the base plate 210 by reducing a motion such as a pitch motion and/or a roll motion with respect to the Y-axis direction 20.

However, this is only an example, and four first springs 255 may not only prevent the twisting of the base plate 210 by an interaction between the first springs 255 close to each other, but may also prevent the twisting of the base plate 210 by an interaction between the first springs 255 spaced apart from each other as much as possible. That is, one or more of the four first springs 255 may interact with each other to minimize the twisting of the base plate 210.

The first vertical shaft 256 may be surrounded by the first springs 255 (see FIG. 4). The first vertical shaft 256 may penetrate through each of the first through hole 210H1 and the first through-hole 251H1, and may be provided with the expansion plate 256A having a greater diameter than the first through hole 210H1. That is, the first vertical shaft 256 may be prevented from being separated from the base plate 210.

The first cover 257 may cover an upper end of the first vertical shaft 256. Referring to FIG. 4, it has been illustrated that the first cover 257 is coupled to the first vertical shaft 256 by a bolt, but the present disclosure is not limited thereto, and as another example, several modified examples such as a modified example in which the first cover 257 is coupled to the reinforcing plate 251 by a method such as welding and/or adhesion are possible.

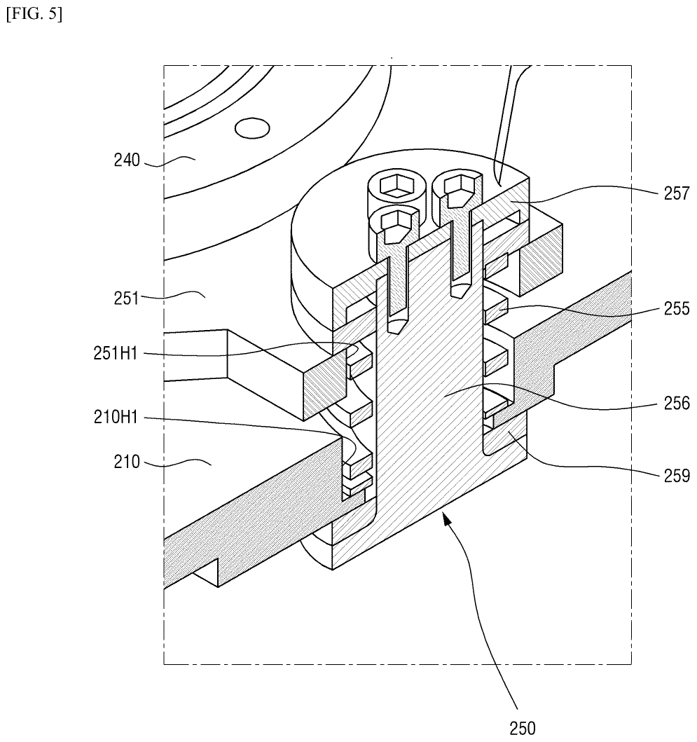

Hereinafter, a modified example of the present exemplary embodiment will be described with reference to FIG. 5, and an overlapping description of the same components performing the same functions will be omitted.

FIG. 5 is a view illustrating a portion of an apparatus of absorbing a vibration according to a second exemplary embodiment of the present disclosure. Contents different from those described with reference to FIGS. 1 to 4 will be mainly described with reference to FIG. 5.

Referring to FIG. 5, an apparatus 200 of absorbing a vibration according to a second exemplary embodiment may include a support shaft 220, a first vibration absorbing unit 250, and a second vibration absorbing unit 230 identically or similarly to the apparatus 200 of absorbing a vibration according to a first exemplary embodiment.

Meanwhile, the first vibration absorbing unit 250 according to a second exemplary embodiment may further include a first block 259. The first block 259 may be provided so that a space for the extension of the first springs 255 is secured.

The first block 259 may be provided between the first cover 257 and the reinforcing plate 251 or provided between the expansion plate 256A and the base plate 210. Alternatively, the first blocks 259 may be provided between the first cover 257 and the reinforcing plate 251 and provided between the expansion plate 256A and the base plate 210.

The first block 259 may be made of a metal material. The first block 259 may include an elastic material, may be made of, for example, a rubber material, and may have a ring shape, but is not limited thereto.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. An apparatus of absorbing a vibration for a transferring vehicle that absorbs a vibration of the transferring vehicle, the transferring vehicle including a driving unit and two pairs of wheels, comprising:
a support shaft supporting the transferring vehicle above a base plate provided between the transferring vehicle and a hoist; and
a first vibration absorbing unit provided on the base plate and reducing twisting of the base plate,
wherein the first vibration absorbing unit includes:
a reinforcing plate provided above the base plate; and
a plurality of first springs provided to be spaced apart from each other at an edge of the reinforcing plate and elastically support the reinforcing plate between the reinforcing plate and the base plate.

2. The apparatus of absorbing a vibration for a transferring vehicle of claim 1, wherein the first vibration absorbing unit further includes a first vertical shaft surrounded by the first springs.

3. The apparatus of absorbing a vibration for a transferring vehicle of claim 2, wherein a first through hole is formed in the base plate and a first through-hole vertically facing the first through hole is formed in the reinforcing plate,
the first vertical shaft penetrates through each of the first through hole and the first through-hole, and is provided with an expansion plate having a greater diameter than the first through hole, and
the first vibration absorbing unit further includes a first cover covering an upper end of the first vertical shaft and coupled to the first vertical shaft or the reinforcing plate.

4. The apparatus of absorbing a vibration for a transferring vehicle of claim 3,
wherein a step with which the first spring is in contact is formed in the first through hole.

5. The apparatus of absorbing a vibration for a transferring vehicle of claim 3,
wherein the first vibration absorbing unit further includes a first block provided between the first cover and the reinforcing plate or provided between the expansion plate and the base plate.

6. The apparatus of absorbing a vibration for a transferring vehicle of claim 5,
wherein the first block includes a metal material or an elastic material and has a ring shape.

7. The apparatus of absorbing a vibration for a transferring vehicle of claim 1,
wherein the first vibration absorbing unit further includes a damper supporting the reinforcing plate so that the base plate and the reinforcing plate are not in contact with each other and are spaced apart from each other.

8. The apparatus of absorbing a vibration for a transferring vehicle of claim 7,
wherein the damper includes a second spring elastically supporting a portion between the reinforcing plate and the base plate at a central portion of the reinforcing plate.

9. The apparatus of absorbing a vibration for a transferring vehicle of claim 8,
wherein a second through-hole through which the second spring penetrates is formed in the reinforcing plate, and
the damper further includes a second cover covering the second through-hole and in contact with the second spring.

10. The apparatus of absorbing a vibration for a transferring vehicle of claim 1,
wherein the first springs are provided to be spaced apart from each other as much as possible from each other at the reinforcing plate.

11. The apparatus of absorbing a vibration for a transferring vehicle of claim 1, wherein two pairs of first springs are provided.

12. The apparatus of absorbing a vibration for a transferring vehicle of claim 11, wherein two support shafts are provided to be spaced apart from each other in an X-axis direction that is a moving direction of the transferring vehicle, and
the first springs are disposed in pairs in a Y-axis direction based on the support shafts in the Y-axis direction perpendicular to the X-axis direction.

13. The apparatus of absorbing a vibration for a transferring vehicle of claim 1, further comprising a second vibration absorbing unit including a vertical vibration absorbing spring elastically supporting a lower portion of the support shaft.

14. The apparatus of absorbing a vibration for a transferring vehicle of claim 13, wherein the second vibration absorbing unit further includes a second vertical shaft surrounded by the vertical vibration absorbing spring.

15. The apparatus of absorbing a vibration for a transferring vehicle of claim 14, wherein a second through hole is formed in the base plate, a third through-hole vertically facing the second through hole is formed in the reinforcing plate, and the second vertical shaft penetrates through each of the second through hole and the third through-hole, and
the second vibration absorbing unit further includes a guider which is in contact with the vertical vibration absorbing spring and into which the second vertical shaft is inserted.

16. The apparatus of absorbing a vibration for a transferring vehicle of claim 15, wherein the guider includes:
a support pillar coupled into the second through hole, supporting the vertical vibration absorbing spring, and having an lower end that are expanded; and
a second block provided between the base plate and the support pillar.

17. The apparatus of absorbing a vibration for a transferring vehicle of claim 16, wherein the second vertical shaft has an upper end that is expanded, is elastically supported on an upper end of the vertical vibration absorbing spring, and is provided to be vertically slidable in the support pillar.

18. A transferring vehicle system comprising:
a transferring vehicle including a driving unit and two pairs of wheels; and
the apparatus of absorbing a vibration for a transferring vehicle of claim 1.

19. A transferring vehicle system, comprising:
a transferring vehicle including a driving unit and two pairs of wheels; and
an apparatus of absorbing a vibration including a base plate which is provided between the transferring vehicle and a hoist and in which a first through hole having a step and a second through hole positioned to be spaced apart from the first through hole are formed, a support shaft supporting the transferring vehicle above the base plate, a first vibration absorbing unit provided on the base plate and reducing twisting of the base plate, and a second vibration absorbing unit provided on the base plate and absorbing a vertical vibration of the base plate,
wherein the first vibration absorbing unit includes:
a reinforcing plate in which a first through-hole vertically facing the first through hole, a second through-hole spaced apart from the first through-hole, and a third-through hole spaced apart from the second through-hole and vertically facing the second through hole are formed and which is provided above the base plate;
a damper supporting the reinforcing plate so that the base plate and the reinforcing plate are not in contact with each other and are spaced apart from each other;
four first springs provided to be spaced apart from each other at an edge of the reinforcing plate, elastically support the reinforcing plate between the reinforcing plate and the base plate, and in contact with and supported by the step of the first through hole;
a first vertical shaft surrounded by the first springs, penetrating through each of the first through hole and the first through-hole, and provided with an expansion plate having a greater diameter than the first through hole;
a first cover covering an upper end of the first vertical shaft and coupled to the first vertical shaft; and
first blocks provided between the first cover and the reinforcing plate and between the expansion plate and the base plate, made of a metal material, and having a ring shape,
the second vibration absorbing unit includes:
a vertical vibration absorbing spring elastically supporting a lower portion of the support shaft;
a second vertical shaft surrounded by the vertical vibration absorbing spring and penetrating through each of the second through hole and the third through-hole; and
a guider which is in contact with the vertical vibration absorbing spring and into which the second vertical shaft is inserted,
the damper includes a second cover coupled to an upper surface of the reinforcing plate at a central portion of the reinforcing plate to cover the second through-hole and a second spring in contact with the second cover to elastically support the reinforcing plate,
the guider includes a support pillar coupled into the second through hole, supporting the vertical vibration absorbing spring, and having an lower end that are expanded, and a second block provided between the base plate and the support pillar, and
the second vertical shaft has an upper end that is expanded, is elastically supported on an upper end of the vertical vibration absorbing spring, and is provided to be vertically slidable in the support pillar.
